(19) United States
(12) Patent Application Publication
(10) Pub. No.: US 2025/0329357 A1
(43) Pub. Date: Oct. 23, 2025

(54) MEMORY SYSTEM AND MEMORY OPERATION METHOD

(71) Applicant: MACRONIX INTERNATIONAL CO., LTD., HSINCHU (TW)

(72) Inventor: Yu-Hsuan LIN, Taichung City (TW)

(21) Appl. No.: 18/884,372

(22) Filed: Sep. 13, 2024

Related U.S. Application Data
(60) Provisional application No. 63/634,938, filed on Apr. 17, 2024.

(51) Int. Cl. G11C 7/10

(52) U.S. Cl. CPC G11C 7/1078

(57) ABSTRACT

A memory operation method, including: applying a first programming signal to a memory cell, wherein a first pulse voltage of the first programming signal is less than a target voltage; applying a second programming signal to the memory cell, wherein a magnitude of the second programming signal is less than a magnitude of the first programming signal; and reading a programming state of the memory cell to determine whether the programming state matches a target state corresponding to the target voltage. Accordingly, the state distribution within the programmed memory cell can be more tighter and precise.

### CROSS-REFERENCE TO RELATED APPLICATION

This application claims priority to U.S. Provisional Application Ser. No. 63/634,938, filed Apr. 17, 2024, which is herein incorporated by reference in its entirety.

### BACKGROUND

### Technical Field

The present disclosure relates to a memory programming technology, particularly a memory system and a memory operation method.

### Description of Related Art

With the development of memory technology, the density of memory cells has become higher and higher, and the data content that can be stored has also increased accordingly. However, the operation method of the memory also need to be adjusted and improved accordingly so that the memory can perform as expected.

### SUMMARY

One aspect of the present disclosure is a memory operation method, comprising: applying a first programming signal to at least one memory cell, wherein a first pulse voltage of the first programming signal is less than a target voltage; applying a second programming signal to the at least one memory cell, wherein a magnitude of the second programming signal is less than a magnitude of the first programming signal; and reading a programming state of the at least one memory cell to determine whether the programming state matches a target state corresponding to the target voltage. Accordingly, the state distribution within the programmed memory cell can be more tighter and precise.

In one embodiment, the first pulse voltage of the first programming signal is greater than a second pulse voltage of the second programming signal. Accordingly, the programming operation will be completed faster and more accurately to improve the efficiency of the programming operation.

In one embodiment, a first pulse time of the first programming signal is greater than a second pulse time of the second programming signal. Accordingly, the programming operation will be completed faster and more accurately to improve the efficiency of the programming operation.

In one embodiment, the first programming signal is applied to the at least one memory cell in a first run, the second programming signal is applied to the at least one memory cell in a second run, and the second run is executed after the first run. Accordingly, the programming state of the memory cell will be determined more accurately and immediately.

In one embodiment, the first pulse voltage is between 70% and 80% of the target voltage. Accordingly, the programming state of the memory cell can be approached to the target state faster.

In one embodiment, The memory operation method of claim 1, further comprising: applying a third programming signal to the at least one memory cell, wherein a magnitude of the third programming signal is less than the magnitude of the second programming signal, and a magnitude difference between the first programming signal and the second programming signal is equal to a magnitude difference between the second programming signal and the third programming signal. Accordingly, the programming state of the memory cell can stably approach the target state.

In one embodiment, the at least one memory cell comprises a plurality of memory cells, and applying the second programming signal to the at least one memory cell comprises: applying the second programming signal to the plurality of memory cells after applying the first programming signal to the plurality of memory cells in sequence. Accordingly, the programming time in a programming run will be greater than a relaxation time of the memory cell.

In one embodiment, a time length that the first programming signal is applied to the plurality of memory cells is between 1 and 100 milliseconds. Accordingly, a read result of the memory cell by the processor can be more accurate.

Another aspect of the present disclosure is a memory operation method, comprising: applying a plurality of programming signals to at least one memory cell in sequence during a programming period, wherein a plurality of magnitudes of the plurality of programming signals gradually decreases in sequence and less than a target voltage; and reading a programming state of the at least one memory cell to determine whether the programming state matches a target state corresponding to the target voltage. Accordingly, the state distribution within the programmed memory cell can be more tighter and precise.

In one embodiment, a plurality of pulse voltages of the plurality of programming signals gradually decreases in sequence. Accordingly, the programming operation will be completed faster and more accurately to improve the efficiency of the programming operation.

In one embodiment, a plurality of pulse times of the plurality of programming signals gradually decreases in sequence. Accordingly, the programming operation will be completed faster and more accurately to improve the efficiency of the programming operation.

In one embodiment, the programming period comprises a plurality of runs, and applying the plurality of programming signals to the at least one memory cell comprises: applying a plurality of first programming signals to the at least one memory cell in sequence in a first run; and applying a plurality of second programming signals to the at least one memory cell in sequence in a second run, wherein a magnitude of the plurality of first programming signals is greater a magnitude of the plurality of second programming signals. Accordingly, the programming state of the memory cells will be determined more accurately and immediately.

In one embodiment, the programming period comprises a plurality of runs, and applying the plurality of programming signals to the at least one memory cell comprises: decrementing a first component of the plurality of programming signals in a same one of the plurality of runs; and decrementing a second component of the plurality of programming signals in different ones of the plurality of runs, wherein the first component is different from the second component. Accordingly, the programming state of the memory cells will be adjusted more accurately.

In one embodiment, the at least one memory cell comprises a plurality of memory cells, and applying the plurality of programming signals to the at least one memory cell comprises: after applying a first one of the plurality of programming signals to the plurality of memory cells in sequence, applying a second one of the plurality of programming signals to the plurality of memory cells, wherein a time length that the first one of the plurality of programming signals is applied to the plurality of memory cells is between 1 and 100 milliseconds. Accordingly, a read result of the memory cells by the processor can be more accurate.

Another aspect of the present disclosure is a memory system, comprising a plurality of memory cells and a processor. The processor is coupled to the plurality of memory cells, and is configured to apply a plurality of programming signals to the plurality of memory cells in sequence during a programming period. A plurality of magnitudes of the plurality of programming signals gradually decreases over time and less than a target voltage. The processor is configured to read a programming state of one of the plurality of memory cells to determine whether the programming state matches a target state corresponding to the target voltage. Accordingly, the state distribution within the programmed memory cell can be more tighter and precise.

In one embodiment, a plurality of pulse voltages of the plurality of programming signals gradually decreases over time. Accordingly, the programming operation will be completed faster and more accurately to improve the efficiency of the programming operation.

In one embodiment, a plurality of pulse times of the plurality of programming signals gradually decreases over time. Accordingly, the programming operation will be completed faster and more accurately to improve the efficiency of the programming operation.

In one embodiment, the processor is configured for: applying a plurality of first programming signals to the plurality of programming signals in sequence in a first run; and applying a plurality of second programming signals to the plurality of programming signals in sequence in a second run, wherein a magnitude of the plurality of first programming signals is greater a magnitude of the plurality of second programming signals. Accordingly, the programming state of the memory cells will be determined more accurately and immediately.

In one embodiment, the programming period comprises a plurality of runs, and the processor is configured for: decrementing a first component of the plurality of programming signals in a same one of the plurality of runs; and decrementing a second component of the plurality of programming signals in different ones of the plurality of runs, wherein the first component is different from the second component. Accordingly, the programming state of the memory cells will be adjusted more accurately.

In one embodiment, the processor is configured to apply a first one of the plurality of programming signals to the plurality of memory cells in sequence, and then apply a second one of the plurality of programming signals to the plurality of memory cells, wherein a time length that the first one of the plurality of programming signals is applied to the plurality of memory cells is between 1 and 100 milliseconds. Accordingly, a read result of the memory cells by the processor can be more accurate.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic diagram of a memory system in some embodiments of the present disclosure.

FIG. 2 is a flowchart illustrating a memory operation method in some embodiments of the present disclosure.

FIG. 3A is a waveform diagram of multiple programming signals in some embodiments of the present disclosure.

FIG. 3B is a waveform diagram of multiple programming signals in some embodiments of the present disclosure.

FIG. 3C is a waveform diagram of multiple programming signals in some embodiments of the present disclosure.

FIG. 4 is a waveform diagram of multiple programming signals in multiple runs in some embodiments of the present disclosure.

FIG. 5 is a waveform diagram of multiple programming signals in multiple runs in some embodiments of the present disclosure.

FIG. 6 is a waveform diagram of multiple programming signals in multiple runs in some embodiments of the present disclosure.

FIG. 7 is a waveform diagram of multiple programming signals in multiple runs in some embodiments of the present disclosure.

FIG. 8 is a waveform diagram of multiple programming signals in multiple runs in some embodiments of the present disclosure.

### DETAILED DESCRIPTION

For the embodiment below is described in detail with the accompanying drawings, embodiments are not provided to limit the scope of the present disclosure. Moreover, the operation of the described structure is not for limiting the order of implementation. Any device with equivalent functions that is produced from a structure formed by a recombination of elements is all covered by the scope of the present disclosure. Drawings are for the purpose of illustration only, and not plotted in accordance with the original size.

It will be understood that when an element is referred to as being “connected to” or “coupled to”, it can be directly connected or coupled to the other element or intervening elements may be present. In contrast, when an element to another element is referred to as being “directly connected” or “directly coupled,” there are no intervening elements present. As used herein, the term “and/or” includes an associated listed items or any and all combinations of more.

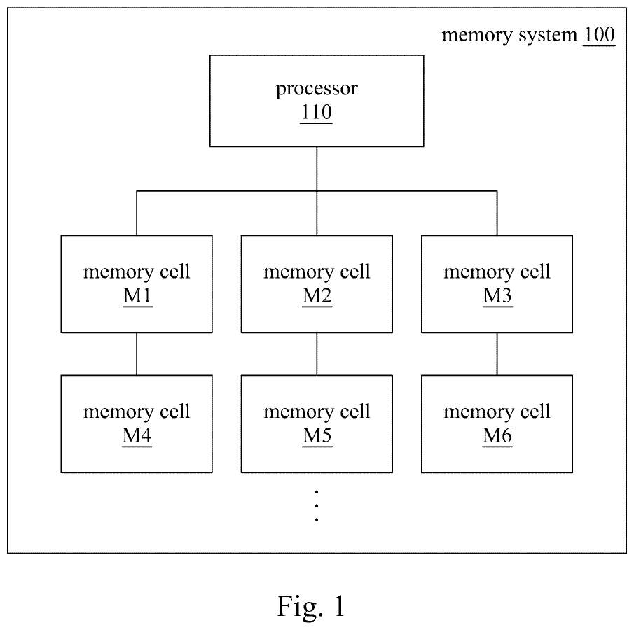

FIG. 1 is a schematic diagram of a memory system 100 in some embodiments of the present disclosure. The memory system 100 includes a processor 110 and multiple memory cells M1-M6 (the number of the memory cells can be adjusted according to product requirements. FIG. 1 shows six memory cells, but the present disclosure is not limited to this). The processor 110 is coupled to the memory cells M1-M6, and is configured to apply one or more programming signals (e.g., pulse voltage) to each of the memory cells M1-M6 in sequence during a programming period, so as to write data to the corresponding memory cell, or erase the corresponding memory cell.

In one embodiment, the memory cells M1-M6 can be implemented by Flash memory, Ferroelectric memory, Resistive memory or Magnetoresistive memory, but the present disclosure is not limited to this.

The term “programming” described in the present disclosure means the operation of “controlling the amount of charge stored in the memory cell to the expected value”. For example, injecting charges into a floating-gate of the memory cell by applying a high voltage, or erasing charges from the floating-gate of the memory cell by applying a negative voltage. In other words, the “programming” described in the following paragraphs can be part of the write operation, or can be part of the erase operation.

Due to unsatisfactory factors (e.g. component impedance, transmission loss), in actual operation, the processor 110 cannot directly use the ideal target voltage as the programming signal to accurately control the programming state of the memory cell at the expected ideal value by applying the ideal target voltage (programming signal) only once. Therefore, the processor 110 must apply the programming signals multiple times to make the programming state in the memory cell approach the target value. In one embodiment, the processor 110 uses Increment Step Pulse Programming (ISPP) to apply multiple different programming signals.

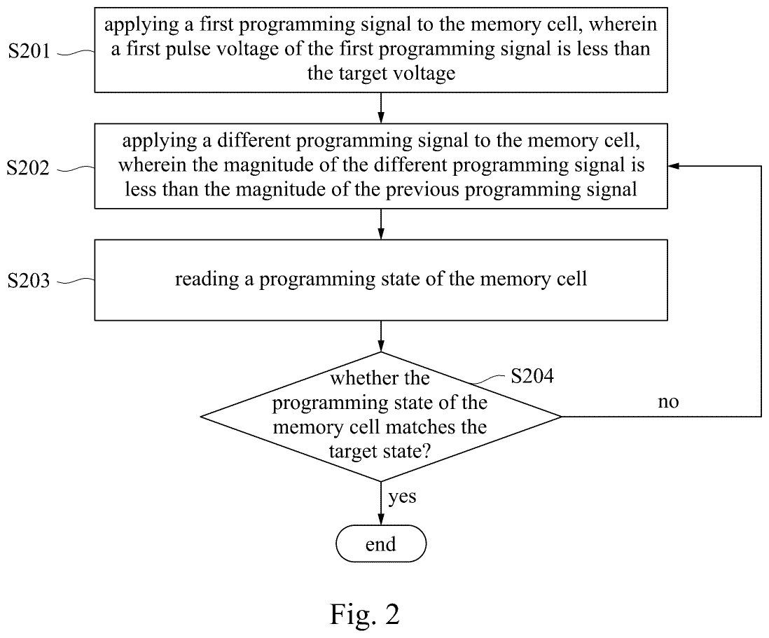

FIG. 2 is taken as an example to illustrate a memory operation method of some embodiments of the present disclosure. In step S201, the processor 110 confirms a target voltage according to a target state (e.g., data “1”). For example, ideally, voltage “10 volts” causes the memory cell to store enough charge to be identified the data “1”. In this example, the target voltage is “10 volts”, and corresponds to an expected storage content (the injected charge, the expected target state). The processor 110 first applies a first programming signal to the memory cell (e.g., the memory cells M1-M6 shown in FIG. 1, and the embodiment takes the memory cell M1 as an example), a first pulse voltage (e.g., 8 volts) of the first programming signal is less than the target voltage, for example, the first pulse voltage is between 70% and 80% of the target voltage.

In step S202, after applying the first programming signal, the processor 110 applies a different programming signal to the memory cell M1, such as a second programming signal. The magnitude of the second programming signal is less than the magnitude of the previous programming signal (e.g., the first programming signal). The term “mentioned” described in the present disclosure can be a pulse voltage or a pulse time of the pulse signal.

In step S203, the processor 110 reads a programming state of the memory cell M1. In step S204, the processor 110 determines (verifies) whether the programming state of the memory cell M1 matches the target state (e.g., data “1”) corresponding to the target voltage.

If the programming state of the memory cell M1 matches the expected target state, it means the programming operation of the memory cell M1 is completed. At this time, the processor 110 can generate a complete message, or can perform the programming operation to other memory cell (e.g., the memory cell M4). If the programming state of the memory cell M1 does not match the expected target state, executing the step S202 again until determining the programming state of the memory cell M1 matches the expected target state in step S203.

In the aforementioned steps S201 to S203, each time the programming signals are applied and the programming state is read, this process is called a “run”. The programming period can include one or more runs, in some embodiments, the processor 110 controls the programming state of the memory cell to gradually approach the target value by multiple runs.

The present disclosure uses the concept of “decrement” to apply multiple programming signals. In other words, during the programming period, multiple programming signals gradually decrease in sequence or gradually decrease over time, and the magnitude of each programming period is less than the target voltage. In one embodiment, the programming signals is a kind of pulse signal (pulse wave), so the magnitude can be a pulse voltage (i.e., voltage value or pulse amplitude) and/or a time length (pulse width) of each pulse. For example, the pulse voltage of the first applied programming signal can be 70-80% of the target voltage. Applying the programming signals through the concept of “decrement” will make the state distribution of the memory cell tighter and precise.

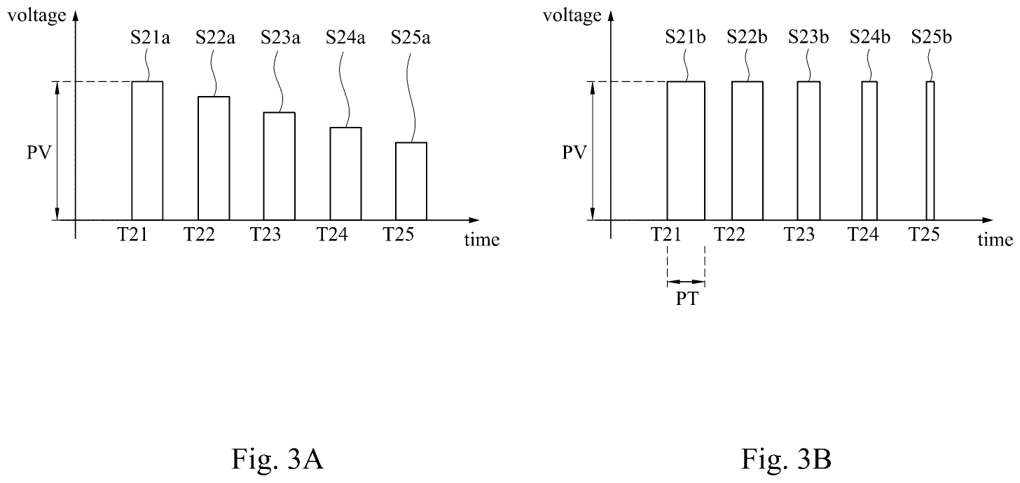

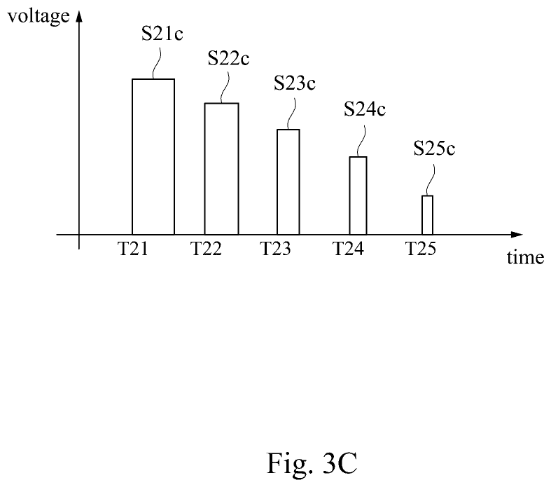

The concept of “decrement” can be implemented by different methods. FIGS. 3A-3C are waveform diagrams of multiple programming signals in some embodiments of the present disclosure. Referring to FIG. 3A, in one embodiment, when the processor 110 programming the memory cell M1, the processor 110 applies multiple programming signals S21a-S25a at multiple time points T21-T25 in sequence, and the pulse voltage PV of the programming signals S21a-S25a gradually decrease over time (application time) or in sequence (application sequence). As shown in FIG. 3A, the first pulse voltage of the first programming signal S21a is greater than the second pulse voltage of the second programming signal S22a, and the second pulse voltage of the second programming signal S22a is greater than the third pulse voltage of the third programming signal S23a.

FIG. 3B shows a programming operation by using another decrement scheme. In one embodiment, the processor 110 applies multiple programming signals S21b-S25b applies multiple programming signals S21b-S25b at multiple time points T21-T25 in sequence, and the pulse time PT of the programming signals S21b-S25b gradually decrease over time (application time) or in sequence (application sequence). As shown in FIG. 3B, the first pulse time of the first programming signal S21b is greater than the second pulse time of the second programming signal S22b, and the second pulse time of the second programming signal S22b is greater than the third pulse time of the third programming signal S23b.

FIG. 3C shows a programming operation by using another decrement scheme. In one embodiment, both of the pulse voltage and the pulse time of the programming signals S21b-S25b gradually decrease over time (application time) or in sequence (application sequence). As shown in FIG. 3C, the first pulse voltage of the first programming signal S21c is greater than the second pulse voltage of the second programming signal S22c, and the first pulse time of the first programming signal S21c is also greater than the second pulse time of the second programming signal S22c.

The present disclosure first applies the programming signal with higher magnitude (but not exceed the target voltage), and then applies other programming signal(s) by the decrement scheme. Therefore, the processor 110 is able to complete the programming operation faster and more accurately to improve the efficiency of the programming operation.

In some embodiments, a magnitude difference (decreasing degree) between multiple programming signals is the same. That is, multiple programming signals will be decreased a same magnitude difference in every programming operation. As shown in FIG. 3A, the pulse voltages of the programming signals S21a-S25a are “8 volts, 7.5 volts, 7 volts, 6.5 volts, 6 volts”, and the magnitude differences are the same. In one embodiment, the magnitude difference (decreasing degree) of the pulse voltages can be between 0.05V and 0.5V. In other words, the magnitude difference between the first programming signal S21a and the second programming signal S22a is equal to the magnitude difference between the second programming signal S22a and the third programming signal S23a.

Similarly, as shown in FIG. 3B, the pulse times of the programming signals S21b-S25b are “20 microseconds, 18 microseconds, 16 microseconds, 14 microseconds, 12 microseconds”, and the magnitude differences are the same (2 microseconds). Accordingly, the programming state of the memory cell M1 can stably approach the target state to improve the accuracy of the operation.

In the aforementioned embodiments, multiple programming signals are applied to the memory cell M1 in the same run in sequence. In other words, the processor 110 first applies multiple programming signals at time points T21-T25, and then reads the programming state of the memory cell M1, so as to determine whether the programming state of the memory cell M1 is matches to the expected target state. Accordingly, since the processor 110 does not need to read the memory cell every time after applying the programming signal, the time required for the programming operation can be reduced. However, the present disclosure is not limited to this. In some embodiments the processor 110 also can apply multiple programming signals in different runs in sequence.

For example, in a first run, the processor 110 applies one or more first programming signal(s) to the memory cell M1. Then, the processor 110 reads the programming state of the memory cell M1. When the programming state does not match the expected target state, the processor 110 executes a second run (the second run is executed after the first run), so as to apply one or more second programming signal(s) to the memory cell M1, and the magnitude of the second programming signal is less than the magnitude of the first programming signal. Accordingly, the programming state of the memory cell M1 will be determined more accurately and immediately.

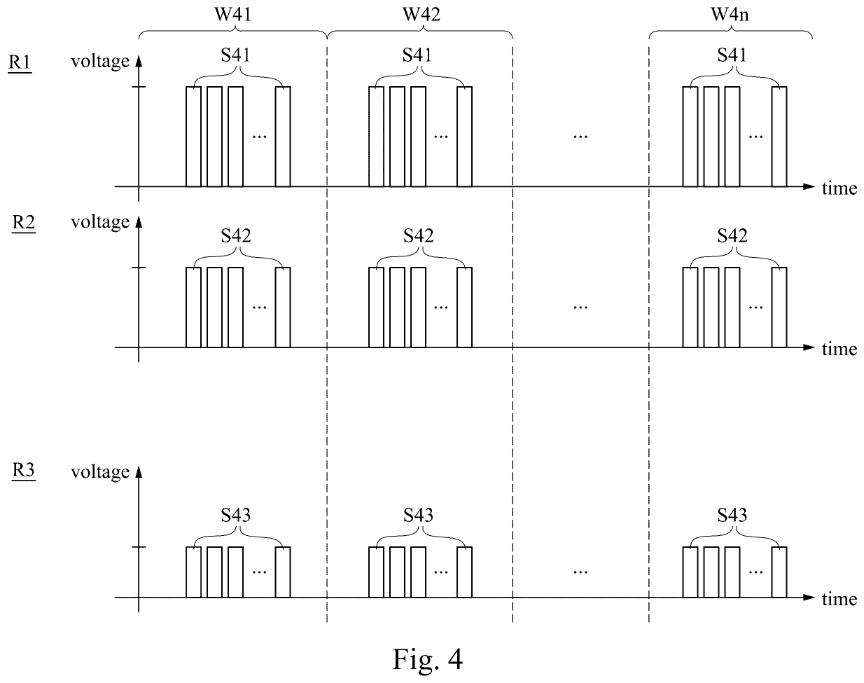

FIG. 4 is a waveform diagram of multiple programming signals in multiple runs R1-R3 in some embodiments of the present disclosure. FIG. 4 shows multiple signal waveforms W41-W4n, and each signal waveform W41-W4n corresponds to different memory cell. For example, in the running R1, the processor 110 first applies one or more first programming signals S41 to the memory cell M1, as shown in the signal waveform W41. Then, in the same run R1, the processor 110 applies the same first programming signals S41 to the memory cell M2, as shown in the signal waveform W42. After applying the first programming signal(s) to N memory cells, the processor 110 sequentially reads the programming state of each memory cell to determine whether the programming state matches the target state.

Similarly, in the run R2, the processor 110 sequentially applies one or more second programming signals S42 to multiple memory cells. If the programming state of the memory cell does not match the target state, then in the run R3, the processor 110 sequentially applies one or more third programming signals to multiple memory cells S43. In other words, the processor 110 can execute a same run of the programming operation for multiple memory cells.

In the embodiment shown in FIG. 4, the magnitude of the programming signals applied by the processor 110 in the same run is the same. For example, in the run R1, the first programming signals S41 applied to the memory cell M1 has the same pulse voltage and the pulse time. Furthermore, the magnitude of the programming signals applied to the processor 110 in different runs is decreasing. For example, the magnitude (the pulse voltage) of the first programming signal S41 is greater than the magnitude of the second programming signal S42, and the first programming signal S41, the second programming signal S42 and the third programming signal S43 have the same decreasing degree.

In the embodiment shown in FIG. 4, the processor 110 applies multiple programming signals with different magnitudes to multiple memory cells in multiple runs. In other words, the processor 110 first applies the programming signals with the same magnitude (e.g., the first programming signal S41) to multiple memory cells. Then, in the next run, the processor 110 applies the programming signals with different magnitudes (e.g., the second programming signal S42) to multiple memory cells.

In one embodiment, the length of time (total time) of “applying one or more programming signals to multiple memory cells” by the processor 110 is greater a relaxation time. “Relax” refers to a phenomenon in which the charge distribution and voltage state of the memory cell gradually change over time after the programming operation is performed on the memory cell. For example, a hundred charges are injected into the floating gate of the memory cell, but after a period of time, part of the charges will be lost (e.g., ten charges are lost). This time (i.e., relaxation time) will vary depending on factors such as electric field, temperature changes, or material properties.

As mentioned above, by applying the programming signals to multiple memory cells in the same run, the time length of applying the programming signals to multiple memory cells by the processor 110 can be controlled to be greater than the relaxation time of the memory cell. After the processor 110 applies the programming signals to multiple memory cells, the processor 110 reads the programming states of the memory cells. Therefore, the processor 110 can provide a more accurate reading result for each memory cell. In one embodiment, the length of time (or relaxation time) can be between 1-100 milliseconds.

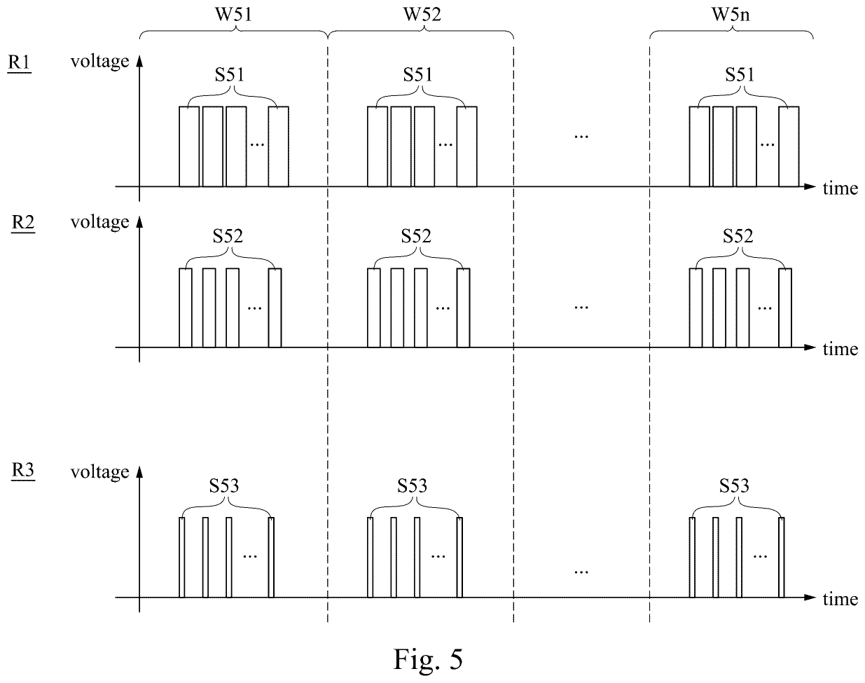

FIG. 5 is a waveform diagram of multiple programming signals applied in multiple runs R1-R3 in some embodiments of the present disclosure. Similar to FIG. 4, each signal waveform W51-W5n corresponds to a different memory cell. As shown in FIG. 5, the magnitudes of the programming signals applied to the processor 110 in the same run is the same. For example, in the run R1, the first programming signals S51 applied to the memory cell M1 has the same pulse voltage and the pulse time. In addition, the magnitudes of the programming signals applied to the processor 110 in different runs are decreasing. For example, the pulse time of the first programming signal S51 is greater than the pulse time of the second programming signal S52, and the first programming signal S51, the second programming signal S52 and the third programming signal S53 have the same decreasing degree.

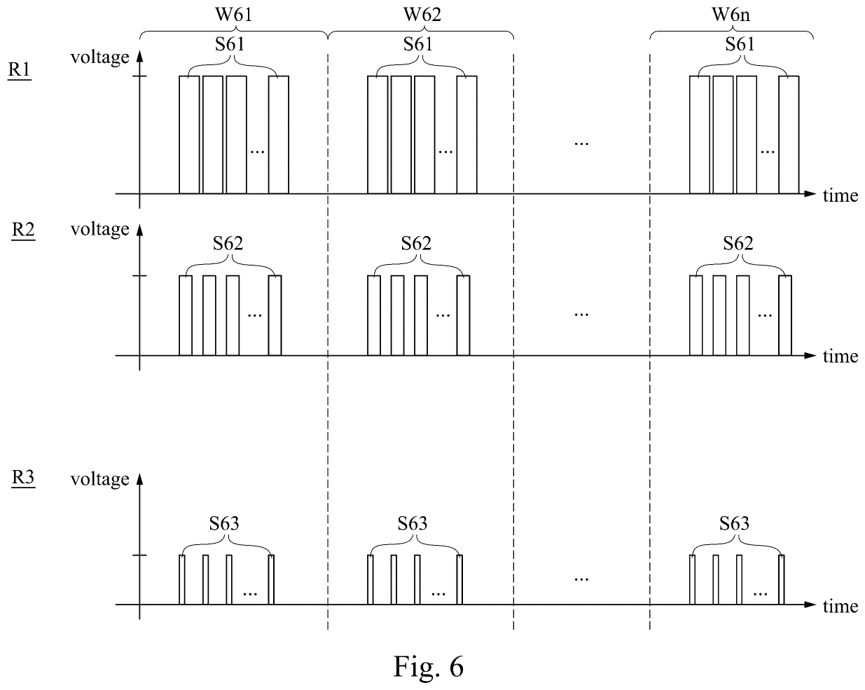

FIG. 6 is a waveform diagram of multiple programming signals applied in multiple runs R1-R3 in some embodiments of the present disclosure. Similar to FIG. 4, each signal waveform W61-W6n corresponds to a different memory cell. As shown in FIG. 6, the magnitudes of the programming signals applied to the processor 110 in the same run is the same. For example, in the run R1, the first programming signals S61 applied to the memory cell M1 has the same pulse voltage and the pulse time. In addition, the magnitudes of the programming signals applied by the processor 110 in different runs are decreasing. For example, the pulse voltage and the pulse time of the first programming signals S61 are both greater than the pulse time of the second programming signals S62, and the first programming signal S61, the second programming signal S62 and the third programming signal S63 have the same decreasing degree.

In the aforementioned embodiments in FIGS. 5-6, the processor 110 can also control the time length of the programming signals are applied to multiple memory cells to be greater than the relaxation time, so the description will not be repeated here.

In the aforementioned embodiments in FIGS. 4-6, the magnitudes of the programming signals provided by the processor 110 in the same run are the same, but the present disclosure is not limited to this. In some other embodiments, the processor 110 can also apply multiple programming signals in the same run by the decrement scheme. For example, the processor 110 applies the first programming signal(s) and the second programming signal(s) in first run, and the magnitude of the first programming signal(s) is greater than the magnitude of the second programming signal(s). Then, in the second run, the processor 110 applies the same combination of decrement programming signals (i.e., the first programming signal(s) and the second programming signal(s)) to the memory cell again. Accordingly, the programming speed of the memory cell will be improved.

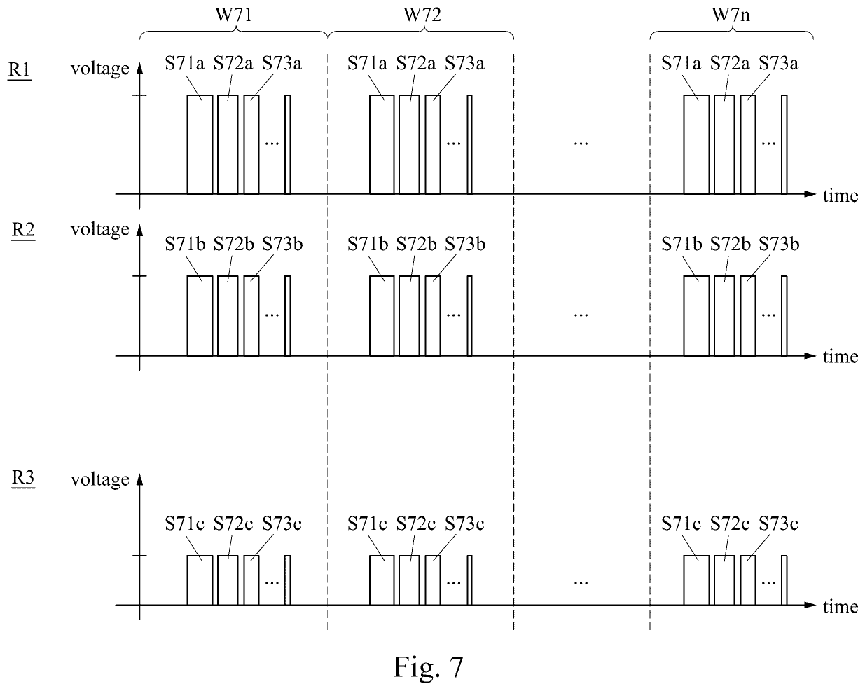

FIG. 7 is a waveform diagram of multiple programming signals in multiple runs in some embodiments of the present disclosure. Similar to FIG. 4, each signal waveform W71-W7n corresponds to a different memory cell. In this embodiment, the processor 110 is configured to decrement a first component of multiple programming signals in a same one of multiple runs, and decrement a second component of multiple programming signals in different ones of multiple runs. The first component is different from the second component. For example, the first component is pulse voltage, and the second component is pulse time. Accordingly, the programming state of the memory cell will be adjusted more accurately.

As shown in FIG. 7, for the same run, the processor 110 is configured to decrement the pulse time of the programming signals. For example, in the run R1, the pulse times of the programming signals S71a-S73a are gradually decrease over time, and have the same decreasing degree.

As mentioned above, for different runs, the processor 110 is configured to decrement the pulse voltage of the programming signals, and the decreasing degrees of the programming signals can remain consistent. For example, all of the pulse voltages of the programming signals S71a-S73a in the run R1 are greater than all of the pulse voltages of the programming signals S71b-S73b in the run R2. Similarly, all of the pulse voltages of the programming signals S71b-S73b in the run R2 are greater than all of the pulse voltages of the programming signals S71c-S73c in the run R3. For example, all of the pulse voltages of the programming signals S71a-S73a are “8 volts”, and all of the pulse voltages of the programming signals S71b-S73b are “7.5 volts”.

Similarly, the processor 110 may also decrement the pulse voltage of the programming signals in the same run, and decrement the pulse time of the programming signals in different runs.

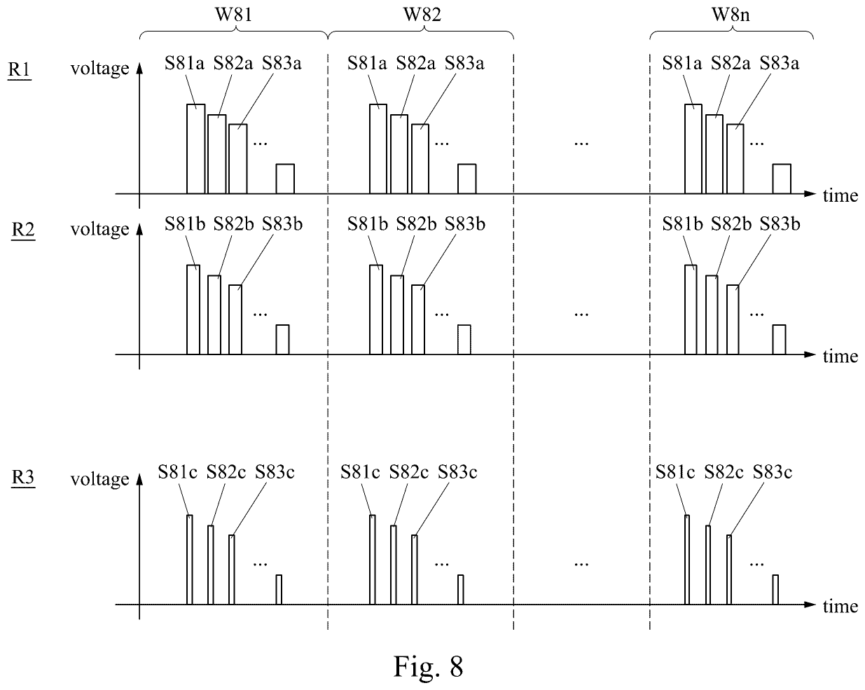

FIG. 8 is a waveform diagram of multiple programming signals in multiple runs in some embodiments of the present disclosure. Similar to FIG. 4, each signal waveform W81-W8n corresponds to a different memory cell. In this embodiment, the processor 110 is configured to decrement both the pulse voltage and the pulse time of the programming signals in the same run, and decrement both the pulse voltage and the pulse time of the programming signals again in the different runs. For example, in the run R1, both the pulse voltage and the pulse time of the programming signals S81a-S83a gradually decrease over time, and have the same decreasing degree.

As mentioned above, processor 110 is configured to decrement both the pulse voltage and the pulse time of the programming signals again. For example, in the run R1, the pulse voltages of the programming signals S71a-S73a are “8 volts, 7.5 volts, 7 volts”, and the pulse times are “10 microseconds, 8 microseconds, 6 microseconds”. In the run R2, the pulse voltages of the programming signals S71b-S73b are “7 volts, 6.5 volts, 6 volts”, and the pulse times are “9 microseconds, 7 microseconds, 5 microseconds”. Similarly, both the pulse time and the pulse voltage of the programming signals S71c-S73c decrease again. Accordingly, the programming operation will be performed with a more obvious decreasing degree, so as to more accurately gradually approach the programming state of the memory cell toward the target state.

The elements, method steps, or technical features in the foregoing embodiments may be combined with each other, and are not limited to the order of the specification description or the order of the drawings in the present disclosure.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

What is claimed is:

1. A memory operation method, comprising:
applying a first programming signal to at least one memory cell, wherein a first pulse voltage of the first programming signal is less than a target voltage;
applying a second programming signal to the at least one memory cell, wherein a magnitude of the second programming signal is less than a magnitude of the first programming signal; and
reading a programming state of the at least one memory cell to determine whether the programming state matches a target state corresponding to the target voltage.

2. The memory operation method of claim 1, wherein the first pulse voltage of the first programming signal is greater than a second pulse voltage of the second programming signal.

3. The memory operation method of claim 1, wherein a first pulse time of the first programming signal is greater than a second pulse time of the second programming signal.

4. The memory operation method of claim 1, wherein the first programming signal is applied to the at least one memory cell in a first run, the second programming signal is applied to the at least one memory cell in a second run, and the second run is executed after the first run.

5. The memory operation method of claim 1, wherein the first pulse voltage is between 70% and 80% of the target voltage.

6. The memory operation method of claim 1, further comprising:
applying a third programming signal to the at least one memory cell, wherein a magnitude of the third programming signal is less than the magnitude of the second programming signal, and a magnitude difference between the first programming signal and the second programming signal is equal to a magnitude difference between the second programming signal and the third programming signal.

7. The memory operation method of claim 1, wherein the at least one memory cell comprises a plurality of memory cells, and applying the second programming signal to the at least one memory cell comprises:
applying the second programming signal to the plurality of memory cells after applying the first programming signal to the plurality of memory cells in sequence.

8. The memory operation method of claim 7, wherein a time length that the first programming signal is applied to the plurality of memory cells is between 1 and 100 milliseconds.

9. A memory operation method, comprising:
applying a plurality of programming signals to at least one memory cell in sequence during a programming period, wherein a plurality of magnitudes of the plurality of programming signals gradually decreases in sequence and less than a target voltage; and
reading a programming state of the at least one memory cell to determine whether the programming state matches a target state corresponding to the target voltage.

10. The memory operation method of claim 9, wherein a plurality of pulse voltages of the plurality of programming signals gradually decreases in sequence.

11. The memory operation method of claim 9, wherein a plurality of pulse times of the plurality of programming signals gradually decreases in sequence.

12. The memory operation method of claim 9, wherein the programming period comprises a plurality of runs, and applying the plurality of programming signals to the at least one memory cell comprises:
applying a plurality of first programming signals to the at least one memory cell in sequence in a first run; and
applying a plurality of second programming signals to the at least one memory cell in sequence in a second run, wherein a magnitude of the plurality of first programming signals is greater a magnitude of the plurality of second programming signals.

13. The memory operation method of claim 9, wherein the programming period comprises a plurality of runs, and applying the plurality of programming signals to the at least one memory cell comprises:
decrementing a first component of the plurality of programming signals in a same one of the plurality of runs; and
decrementing a second component of the plurality of programming signals in different ones of the plurality of runs, wherein the first component is different from the second component.

14. The memory operation method of claim 9, wherein the at least one memory cell comprises a plurality of memory cells, and applying the plurality of programming signals to the at least one memory cell comprises:
after applying a first one of the plurality of programming signals to the plurality of memory cells in sequence, applying a second one of the plurality of programming signals to the plurality of memory cells, wherein a time length that the first one of the plurality of programming signals is applied to the plurality of memory cells is between 1 and 100 milliseconds.

15. A memory system, comprising:
a plurality of memory cells; and
a processor coupled to the plurality of memory cells, and configured to apply a plurality of programming signals to the plurality of memory cells in sequence during a programming period, wherein a plurality of magnitudes of the plurality of programming signals gradually decreases over time and less than a target voltage;
wherein the processor is configured to read a programming state of one of the plurality of memory cells to determine whether the programming state matches a target state corresponding to the target voltage.

16. The memory system of claim 15, wherein a plurality of pulse voltages of the plurality of programming signals gradually decreases over time.

17. The memory system of claim 15, wherein a plurality of pulse times of the plurality of programming signals gradually decreases over time.

18. The memory system of claim 15, wherein the processor is configured for:
applying a plurality of first programming signals to the plurality of programming signals in sequence in a first run; and
applying a plurality of second programming signals to the plurality of programming signals in sequence in a second run, wherein a magnitude of the plurality of first programming signals is greater a magnitude of the plurality of second programming signals.

19. The memory system of claim 15, wherein the programming period comprises a plurality of runs, and the processor is configured for:
decrementing a first component of the plurality of programming signals in a same one of the plurality of runs; and
decrementing a second component of the plurality of programming signals in different ones of the plurality of runs, wherein the first component is different from the second component.

20. The memory system of claim 15, wherein the processor is configured to apply a first one of the plurality of programming signals to the plurality of memory cells in sequence, and then apply a second one of the plurality of programming signals to the plurality of memory cells, wherein a time length that the first one of the plurality of programming signals is applied to the plurality of memory cells is between 1 and 100 milliseconds.
